(19) United States
(12) Patent Application Publication
(10) Pub. No.: US 2026/0157174 A1
(43) Pub. Date: Jun. 4, 2026

(54) HEAT DISSIPATION MODULE AND SEMICONDUCTOR PACKAGING STRUCTURE

(71) Applicant: MIIN-JANG CHEN, Taipei City (TW)

(72) Inventor: MIIN-JANG CHEN, Taipei City (TW)

(21) Appl. No.: 19/406,712

(22) Filed: Dec. 2, 2025

Related U.S. Application Data
(60) Provisional application No. 63/726,843, filed on Dec. 2, 2024.

(51) Int. Cl. H10W 40/20; H10W 40/25; H10W 70/63; H10W 90/00; H10W 90/26

(52) U.S. Cl. CPC H10W 40/242; H10W 40/259; H10W 70/635; H10W 90/401; H10W 90/724; H10W 90/26; H10W 90/722

(57) ABSTRACT

A heat dissipation module includes a heat-dissipating device and an ultra-thin thermally conductive insulating layer formed to overlay a predetermined surface of the heat-dissipating device. The ultra-thin thermally conductive insulating layer is formed by an atomic layer deposition (ALD)-based process, and features a thickness of no greater than 50 nanometers and a substantially low leakage current density. The ultra-thin thermally conductive insulating layer can effectively reduce the thermal resistance and enables contact with a thermal interface material (TIM) without causing electrical short circuits.

### CROSS-REFERENCE TO RELATED APPLICATION

This utility application claims priority to U.S. Provisional Application Ser. No. 63/726,843, filed Dec. 2, 2024, which is incorporated herein by reference.

### BACKGROUND OF THE INVENTION

### 1. Field of the Invention

The present invention relates to a heat dissipation module and a semiconductor packaging structure incorporating the same, and more particularly, to a heat dissipation module utilizing an ultra-thin thermally conductive insulating layer exhibiting a high thermal conductance per unit area and a substantially low leakage current density, and to a semiconductor packaging structure incorporating the same.

### 2. Description of the Prior Art

With the continuous scaling of semiconductor technology in accordance with Moore's Law, the integration level of integrated circuit (IC) devices continues to increase. As driven by the development of high-performance computing (HPC), artificial intelligence (AI) chips, and high-frequency communication devices, the power density within a single chip or packaging module is increasing significantly. When excessive heat accumulates in a limited volume and cannot be effectively dissipated, it may lead to excessive chip temperature, resulting in severe problems such as degraded chip performance, reduced reliability, or even device failure. Therefore, “thermal management” has become a key bottleneck restricting the performance of next-generation electronic products.

In a conventional electronic packaging architecture, a heat dissipation path involves heat generated from the active region of a chip, passing through a passivation layer on a surface of the chip, then through a thermal interface material (TIM) and a heat spreader to a heat sink, and ultimately dissipated to the environment. Each contact interface generates contact thermal resistance, and each layer of material itself also has intrinsic thermal resistance.

A significant challenge faced by the prior art is that “thermal conduction” and “insulation” properties are often difficult to concurrently achieve, which is specifically manifested in the following aspects.

First, regarding the limitations of thermal interface materials (TIMs): TIMs are typically configured to fill gaps between rough contact surfaces. To enhance thermal conductivity (k), the industry often incorporates high thermal conductivity fillers, such as silver, copper, graphene, or carbon nanotubes, into polymer matrices. However, these high-performance fillers typically possess electrical conductivity. When a filler concentration exceeds a percolation threshold to achieve high thermal performance, the TIM may transform into an electrically conductive material due to the formation of a continuous conduction network by the fillers. If such conductive TIMs are directly applied to surfaces of a chip or a device without proper insulation treatment, a risk of short circuits is significantly increased. Therefore, to ensure electrical safety, the prior art is often limited to using fillers with lower thermal conductivity, such as ceramics (e.g., alumina), or to limiting a proportion of metal fillers, thereby sacrificing heat dissipation performance.

Second, concerning the thermal resistance of passivation layers and insulating layers: insulating liners are usually required on a surface of a chip or on inner walls of through-silicon vias (TSVs) in silicon interposers to prevent leakage. Conventionally, these insulating liners are formed of silicon dioxide (SiO₂) or silicon nitride (SiNₓ) by thermal oxidation, chemical vapor deposition (CVD), or plasma-enhanced chemical vapor deposition (PECVD) processes, with thicknesses typically ranging from hundreds of nanometers to several micrometers. However, the intrinsic thermal conductivity of SiO₂ and SiNₓ is relatively low (SiO₂ is about 1.4 W/m·K), and thicker insulating layers form significant thermal resistance barriers. Particularly in 2.5D, 3D, and other advanced semiconductor packaging structures, TSVs serve as critical paths for vertical heat conduction. If the insulating liner on the inner walls of TSVs has an excessively high thermal resistance, it may substantially impede the ability of heat to conduct radially outward from the interior of stacked chips, thereby limiting the overall heat dissipation efficiency.

Third, regarding heat transfer mechanisms at the nanoscale: According to the thermal resistance formula (described in detail below), when a thickness of an insulating thin film is reduced to the nanometer level (e.g., less than 10 nanometers), a contribution of an intrinsic thermal resistance of the thin film material is significantly reduced, and at this point, a total thermal resistance is primarily dominated by “interfacial thermal resistance.” However, simply reducing the thickness of the insulating layer fabricated by conventional chemical vapor deposition (CVD) processes often leads to a substantial increase in leakage current density due to a high density of pinholes or defects, resulting in degradation or loss of insulating performance. Therefore, reducing the thickness of the insulating layer to a maximum extent without sacrificing electrical insulation is an effective way to improve overall heat dissipation efficiency.

Furthermore, for materials with high thermal conductivity such as aluminum nitride (AlN), thin films deposited by conventional atomic layer deposition (ALD) processes at low temperatures (e.g., below 300° C.) typically exhibit either amorphous or polycrystalline structures, wherein grain boundary scattering substantially impedes phonon transport, resulting in a thermal conductivity significantly below the corresponding bulk theoretical value. In addition, for two-dimensional materials such as boron nitride (BN), if their lattice orientation is not sufficiently controlled, their high in-plane thermal conductivity may not effectively contribute to out-of-plane heat dissipation paths, thereby limiting an overall heat dissipation efficiency.

Therefore, in the field of heat dissipation technology, there is an urgent need for an innovative solution that can concurrently achieve a substantially low leakage current (providing excellent insulation) and a substantially low thermal resistance (providing efficient heat dissipation) at ultra-thin insulating layer thicknesses (e.g., less than 50 nanometers), and that can tailor the microstructure of the material for different application scenarios (e.g., heat-dissipating devices, TSVs, chip surfaces), so as to overcome the performance bottlenecks of existing heat dissipation modules and advanced semiconductor packaging architectures.

### SUMMARY OF THE INVENTION

Accordingly, one aspect of the present invention is to provide a heat dissipation module and a semiconductor packaging structure incorporating the same. The heat dissipation module and the semiconductor packaging structure incorporating such heat dissipation module according to embodiments of the present invention utilize an “ultra-thin thermally conductive insulating layer” that is formed by an atomic layer deposition based (ALD-based) process. The ultra-thin thermally conductive insulating layer has a nanoscale thickness, exhibits substantially low leakage current density, and provides high heat transfer characteristics, thereby addressing the problem in the prior art where thermal conduction and electrical insulation performance are difficult to concurrently achieve.

According to a first preferred embodiment of the present invention, a heat dissipation module includes a heat-dissipating device and an ultra-thin thermally conductive insulating layer. The heat-dissipating device has a predetermined surface, and the ultra-thin thermally conductive insulating layer is formed to overlay the predetermined surface of the heat-dissipating device. The ultra-thin thermally conductive insulating layer is formed by an ALD-based process. The thickness of the ultra-thin thermally conductive insulating layer is equal to or less than 50 nanometers, and the leakage current density of the ultra-thin thermally conductive insulating layer is equal to or less than 10⁻⁶ A/cm².

In one embodiment, the ALD-based process may include, but is not limited to, a conventional thermal atomic layer deposition (thermal-ALD) process, an atomic layer annealing-enhanced atomic layer deposition (ALA-ALD) process, a hydrogen-manipulated atomic layer deposition (HM-ALD) process, a plasma-activated precursor atomic layer deposition (PAP-ALD) process, an ultraviolet (UV)-enhanced atomic layer deposition process, a plasma-enhanced atomic layer deposition (PEALD) process, a multiple-pulse atomic layer deposition process, an exposure-mode atomic layer deposition process, or other ALD-based processes, or combinations thereof.

In one embodiment, the heat-dissipating device includes a heat sink or a heat spreader. The predetermined surface is a contact surface configured to interface with a thermal interface material. The ultra-thin thermally conductive insulating layer is configured to provide electrical insulation between the heat sink or the heat spreader and the thermal interface material while facilitating thermal conduction therebetween.

In another embodiment, the heat-dissipating device includes a silicon interposer. The predetermined surface is an inner wall of a through-silicon via (TSV) in the silicon interposer. The ultra-thin thermally conductive insulating layer serves as an insulating liner to electrically isolate the conductive material disposed within the TSV from the silicon interposer and to provide a radial heat conduction path.

In one embodiment, the ultra-thin thermally conductive insulating layer according to the present invention may be formed of a metal oxide or a metalloid oxide. The metal oxide or the metalloid oxide may be selected from the group consisting of HfO₂, ZrO₂, HfₓZr^{1-x}O₂ (0≤x≤1), Ta₂O₃, Al₂O₃, Gd₂O₃, La₂O₃, SiO₂, TiO₂, Y₂O₃, other metal oxides, other metalloid oxides, and combinations thereof.

In another embodiment, the ultra-thin thermally conductive insulating layer according to the present invention is formed of a metal nitride or a metalloid nitride. The metal nitride or the metalloid nitride may be selected from the group consisting of AlNₓ, SiNₓ, GeNₓ, BNₓ, other metal nitrides, other metalloid nitrides, and combinations thereof, wherein 0.5≤x≤1.5.

In one embodiment, the thickness range of the ultra-thin thermally conductive insulating layer ranges from 3 nanometers to 50 nanometers. The thermal conductance per unit area of the ultra-thin thermally conductive insulating layer is equal to or greater than 50 MW/m²·K.

According to a second preferred embodiment of the invention, a semiconductor packaging structure includes a substrate, an interposer, a plurality of metal plugs, a plurality of first bumps, at least one chiplet, and a first ultra-thin thermally conductive insulating layer. The interposer is disposed over the substrate and defines a plurality of interposer vias extending therethrough. The interposer is a silicon interposer or a glass interposer. Wherein, when the interposer is the silicon interposer, the plurality of interposer vias are a plurality of through-silicon vias (TSVs); and when the interposer is the glass interposer, the plurality of interposer vias are a plurality of through-glass vias (TGVs). Each of the plurality of metal plugs is disposed within a corresponding one of the plurality of interposer vias. Each of the plurality of first bumps is electrically coupled between the substrate and a corresponding one of the plurality of metal plugs. The at least one chiplet is disposed on the interposer. Each chiplet includes a plurality of second bumps, wherein each of the plurality of second bumps is electrically coupled to a corresponding one of the plurality of metal plugs. The first ultra-thin thermally conductive insulating layer is conformally disposed over at least portions of the at least one chiplet, the interposer, the plurality of first bumps, and the plurality of second bumps. The first ultra-thin thermally conductive insulating layer is formed by a first ALD-based process. A first thickness of the first ultra-thin thermally conductive insulating layer is equal to or less than 50 nanometers, and a first leakage current density of the first ultra-thin thermally conductive insulating layer is equal to or less than 10⁻⁶ A/cm².

In embodiments wherein the interposer is the silicon interposer and the plurality of interposer vias are the plurality of through-silicon vias, the semiconductor packaging structure according to the second embodiment of the invention further includes a plurality of second ultra-thin thermally conductive insulating layers. Each of the plurality of the second ultra-thin thermally conductive insulating layers corresponds to one of the plurality of through-silicon vias, and is formed to overlay a respective inner wall of the corresponding through-silicon via. The plurality of the second ultra-thin thermally conductive insulating layers are formed by a second ALD-based process. A second thickness of each of the plurality of the second ultra-thin thermally conductive insulating layer is equal to or less than 50 nanometers, and a second leakage current density of each of the plurality of the second ultra-thin thermally conductive insulating layer is equal to or less than 10⁻⁶ A/cm².

In one embodiment, the first ALD-based process and the second ALD-based process are independently selected from the group consisting of a conventional thermal atomic layer deposition (thermal-ALD) process, an atomic layer annealing-enhanced atomic layer deposition (ALA-ALD) process, a hydrogen-manipulated atomic layer deposition (HM-ALD) process, a plasma-activated precursor atomic layer deposition (PAP-ALD) process, a UV-enhanced atomic layer deposition process, a plasma-enhanced atomic layer deposition (PEALD) process, a multiple-pulse atomic layer deposition process, an exposure-mode atomic layer deposition process, other ALD-based processes, and combinations thereof.

In one embodiment, the plurality of the first ultra-thin thermally conductive insulating layers and the second ultra-thin thermally conductive insulating layers may respectively be formed of one selected from the group consisting of a metal oxide, a metalloid oxide, a metal nitride and a metalloid nitride. The metal oxide or the metalloid oxide is selected from the group consisting of HfO₂, ZrO₂, HfₓZr₁₋ₓO₂ (0≤x≤1), Ta₂O₃, Al₂O₃, Gd₂O₃, La₂O₃, SiO₂, TiO₂, Y₂O₃, other metal oxides, other metalloid oxides, and combinations thereof. The metal nitride or the metalloid nitride is selected from the group consisting of AlNₓ, SiNₓ, GeNₓ, BNₓ, other metal nitrides, other metalloid nitrides, and combinations thereof, wherein 0.5≤x≤1.5.

In some embodiments, the semiconductor packaging structure according to the second embodiment further includes a chiplet stack. The chiplet stack is disposed on the interposer. The chiplet stack includes a plurality of third bumps. Each of the plurality of the third bumps corresponds to one of the plurality of metal plugs, and is electrically coupled to the corresponding metal plug. The first ultra-thin thermally conductive insulating layer also overlays the entire outer surface of the chiplet stack.

In contrast to the prior art, embodiments of the present invention leverage phonon ballistic transport characteristics of ultra-thin films or specific crystal orientations (e.g., hexagonal boron nitride oriented substantially perpendicular to a surface of the chip) to substantially reduce the thermal resistance of the ultra-thin insulating layer. Concurrently, embodiments of the present invention form a high-quality and ultra-thin thermally conductive insulating layer via an ALD-based process, such that it maintains substantially low thermal resistance while possessing high electrical insulation properties. By virtue of the ultra-thin thermally conductive insulating layer, the heat dissipation module is afforded greater integration margin to interface with TIMs having high thermal conductivity, thereby improving the heat dissipation performance and reliability of 2.5D, 3D, and other advanced semiconductor packaging structures.

The advantage and spirit of the invention may be understood by the following recitations together with the appended drawings.

### BRIEF DESCRIPTION OF THE APPENDED DRAWINGS

FIG. 1 is a graph showing the relationship between the thermal conductance per unit area and the thickness of AlN thin films fabricated using two atomic layer deposition processes according to embodiments of the present invention.

FIG. 2 shows a high-resolution transmission electron microscopy (HRTEM) cross-sectional image and a corresponding fast Fourier transformation (FFT) pattern of a boron nitride thin film deposited on a silicon substrate via a plasma-activated precursor atomic layer deposition (PAP-ALD) process according to one embodiment of the present invention.

FIG. 3 is a schematic cross-sectional diagram of a heat dissipation module according to the first embodiment of the present invention, together with its application environment and associated components thereof.

FIG. 4 is a schematic cross-sectional diagram of another application scenario of the heat dissipation module according to the first embodiment of the present invention.

FIG. 5 is a schematic cross-sectional diagram of a semiconductor package structure according to the second embodiment of the present invention.

FIG. 6 is a schematic cross-sectional diagram of a modification of the semiconductor package structure according to the second embodiment of the present invention.

FIG. 7 is a graph showing the thermal conductance per unit area and leakage current density versus thickness of an aluminum oxide (Al₂O₃) thin film according to one embodiment of the present invention, wherein the Al₂O₃ thin film is formed by a plasma-enhanced atomic layer deposition (PEALD) process and incorporated into metal-insulator-semiconductor (MIS) and metal-insulator-metal (MIM) capacitor devices for leakage current density measurement.

FIG. 8 is a graph showing the thermal conductance per unit area and leakage current density versus thickness of an aluminum nitride (AlN) thin film according to one embodiment of the present invention, wherein the AlN thin film is formed by a hydrogen-manipulated atomic layer deposition (HM-ALD) process and incorporated into MIS and MIM capacitor devices for leakage current density measurement.

### DETAILED DESCRIPTION OF THE INVENTION

To enable the examiner to further understand the features and technical content of the present embodiments of the present invention, please refer to the following detailed description and accompanying drawings. However, the appended drawings are provided merely for reference and illustration and are not intended to limit the scope of the present invention.

Embodiments of the “heat dissipation module” and the “2.5D, 3D, and other advanced semiconductor packaging structures” disclosed herein utilize an “ultra-thin thermally conductive insulating layer”. This functional layer is not a simple material substitution but, rather, is formed through a specific advanced fabrication process, namely, an atomic layer deposition-based process (ALD-based process) that is configured to achieve a substantially low leakage current density and high thermal conduction capability at the nanoscale. The following description will first explain the physical principles and heat transfer mechanisms of this ultra-thin thermally conductive insulating layer, followed by a detailed description of its specific implementations thereof within the heat dissipation module and semiconductor packaging structures.

### I. Physical Principles and Heat Transfer Mechanisms of the Ultra-Thin Thermally Conductive Insulating Layer:

1. Relationship between Thermal Conduction and Interfacial Thermal Resistance:

When a heat flow traverses an interface between different materials, the interfacial thermal resistance (Rᵢₙₜ) impedes heat transmission. The larger the interfacial thermal resistance (Rᵢₙₜ), the more difficult it becomes for the heat to be transferred across the interface is, thereby reducing an overall thermal conductance. For nano-scale insulating thin films, interfacial thermal resistance (Rᵢₙₜ) is one of the factors dominating heat transmission characteristics. The total thermal conductance (Gₜₒₜₐₗ) and total thermal resistance (Rₜₒₜₐₗ) of a thin film are collectively determined by intrinsic thermal conductivity (k) of the material and the interfacial thermal resistance (Rᵢₙₜ), and the combination thereof determines the final heat transmission behavior:

$${R}_{total} = \frac{1}{{G}_{total}} = {R}_{int 1} + {R}_{film} + {R}_{int 2} = {R}_{int 1} + \frac{d}{k \cdot A} + {R}_{int 2} \qquad Equation ( 1 )$$

wherein A is the cross-sectional area, Rᵢₙₜ₁ and Rᵢₙₜ₂ are the interfacial thermal resistances of interface 1 and interface 2, respectively, and R_{film} is the thermal resistance of the thin film itself. As indicated by Equation (1), as the film thickness d decreases, the contribution of interfacial thermal resistance (Rᵢₙₜ₁, Rᵢₙₜ₂) to the total thermal resistance (Rₜₒₜₐₗ) of the film increases; whereby, the total thermal resistance (Rₜₒₜₐₗ) is primarily dominated by the interfacial thermal resistance.

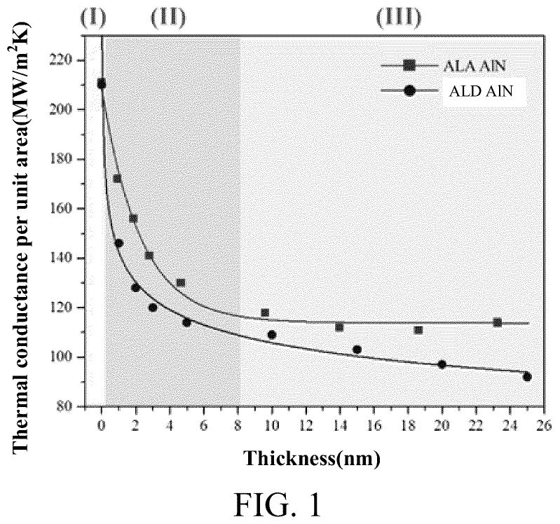

Referring to FIG. 1, FIG. 1 is a graph showing the relationship between the thermal conductance per unit area and the thickness of AlN thin films fabricated on sapphire substrates using two atomic layer deposition-based processes according to embodiments of the present invention, wherein the thermal conductance per unit area values were measured using time-domain thermoreflectance (TDTR). Experiments conducted in accordance with the present invention compared AlN thin films fabricated by a conventional PEALD process (ALD AlN films) with those fabricated by an atomic layer annealing-enhanced atomic layer deposition (ALA-ALD) process (ALA AlN films) in terms of thermal conductance per unit area (G). The ALA process introduces an in-situ He/Ar plasma treatment after each ALD cycle to anneal the atomic-layer AlN. The results show that the crystalline quality of ALA AlN films is superior to that of ALD AlN films. As shown in FIG. 1, for conventional ALD AlN films, G decreases as the film thickness (d) of the ALD AlN films increases. However, when the film thickness is reduced to the nanoscale (e.g., less than 10 nm), the contribution of the intrinsic thermal resistance of the film body

$$( {R}_{film} = \frac{d}{k \cdot A} )$$

the total thermal resistance (Rₜₒₜₐₗ) of the film is dominated by the two interfacial thermal resistances (Rᵢₙₜ₁ and Rᵢₙₜ₂). This indicates that effectively controlling interface quality and reducing thickness can achieve substantially low total thermal resistance. However, thin films formed by conventional chemical vapor deposition (CVD) or physical vapor deposition (PVD) processes often suffer from the presence of excessive voids, grain boundaries, structural defects, and insufficient material density when thinned to such nanoscale dimensions, resulting in substantially increased leakage current and loss of insulating function. The key innovation of the present embodiments of the present invention lies in the use of atomic layer deposition-based processes that enable the insulating layer to maintain substantially low leakage current (providing high insulation performance) even at ultra-thin thicknesses (e.g., 3 nm to 50 nm). In addition, phonon scattering can be reduced by improving crystalline quality or orientation, thereby achieving enhanced thermal conduction. Notably, the thermal conductance per unit area of both ALD AlN and ALA AlN films shown in FIG. 1 reaches levels of tens to hundreds of MW/m²·K.

### 2. Phonon Ballistic Transport:

In materials with high crystalline quality, when the film thickness is less than the phonon mean free path, phonons can travel directly from one side of the film to the other with minimal scattering—a phenomenon known as ballistic transport.

As also shown in FIG. 1, AlN thin films (ALA AlN) formed by embodiments of the present invention using atomic layer annealing-enhanced atomic layer deposition (ALA-ALD) exhibit high crystalline quality, with a thermal conductance per unit area approaching a substantially constant value (designated as Region III) at thicknesses greater than 10 nm and showing substantially no decline with increasing thickness, thereby indicating phonon ballistic transport behavior within the film. This phenomenon suggests that the film itself contributes negligibly to the total thermal resistance, resulting in substantially high thermal transmission efficiency. In contrast, ALD AlN films formed by conventional PEALD processes exhibit poorer crystallinity, causing their thermal conductance per unit area thereof to continue declining with increasing thickness. Therefore, controlling the insulating layer thickness to below 50 nm—particularly between 3 nm and 26 nm—and using ALA technique to enhance film crystalline quality can effectively reduce overall thermal resistance. It must be emphasized that for insulating thin films that concurrently meet product and packaging structure requirements for total thermal resistance and leakage current density, a reduction in film thickness can facilitate shorter manufacturing process times, lower raw material consumption, and greater benefits for production efficiency and cost optimization.

### 3. Vertical Orientation of Anisotropic Thermally Conductive Materials:

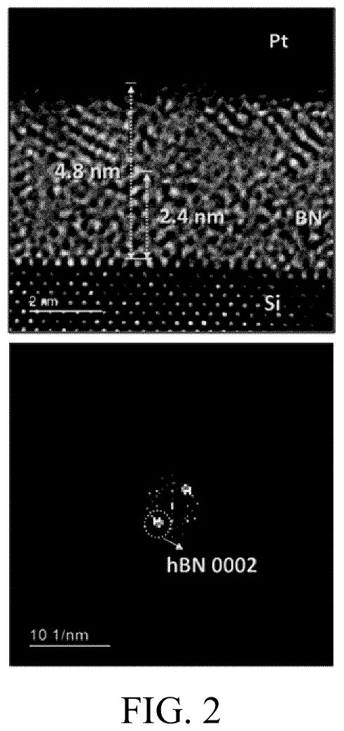

Regarding boron nitride (BN) thin films, hexagonal boron nitride (h-BN) thin films have a layered structure similar to graphene, wherein the thermal conductivity along the basal plane is substantially greater that in the perpendicular direction. Referring to FIG. 2, FIG. 2 shows high-resolution transmission electron microscopy (HRTEM) cross-sectional images of boron nitride thin films deposited on silicon substrates using a plasma-activated precursor atomic layer deposition (PAP-ALD) process according to embodiments of the present invention. Patterns in reciprocal lattice space obtained via fast Fourier transform (FFT) from these images are also shown in FIG. 2. As indicated by FIG. 2, the PAP-ALD process employed in accordance with the present invention facilitates growth of h-BN basal planes in a direction nearly perpendicular to the substrate surface (i.e., basal planes oriented substantially upright). This structure provides an efficient thermal conduction path in the vertical direction, thereby mitigating an inherent disadvantage of two-dimensional materials in vertical heat dissipation.

### II. Detailed Description of Atomic Layer Deposition (ALD)-Based Process Technologies:

It is noted that conventional ALD processes may satisfy requirements for thermal conductance per unit area and leakage current density in certain applications. However, to maintain high insulation performance at ultra-thin insulating layer thicknesses while controlling microstructures, embodiments of the present invention employs modified ALD processes. These processes are characterized by introducing additional energy sources (such as plasma or ultraviolet irradiation) or specialized chemical steps to enhance film quality.

### 1. Atomic Layer Annealing-Enhanced Atomic Layer Deposition (ALA-ALD) Process:

The ALA-ALD process incorporates an additional inert gas (e.g., argon or helium) plasma treatment step after the reactant pulse in each ALD cycle or in selected ALD cycles. Plasma species within the plasma transfer energy to the freshly deposited atomic layer, facilitating migration and rearrangement of surface adatoms, thereby enabling formation of films having enhanced crystallinity or epitaxial growth at low temperatures (e.g., 300° C.)). In one exemplary implementation (using AlN thin films as an example): Step 1: introducing a trimethylaluminum (TMA) precursor pulse; Step 2: performing an argon purge; Step 3: introducing a nitrogen/hydrogen mixed gas plasma as a reactant; Step 4: performing an argon purge; Step 5: performing a helium/argon plasma treatment for in-situ atomic layer annealing (ALA). Experimental data indicates that zirconia (ZrO₂) thin films formed by the ALA-ALD process exhibit a leakage current density (J_{g}) significantly lower than that of films produced by conventional ALD processes, with reductions of approximately 2 to 3 orders of magnitude, demonstrating that ALA-ALD markedly enhances electrical insulation performance.

### 2. Hydrogen-Manipulated Atomic Layer Deposition (HM-ALD) Process:

The HM-ALD process introduces hydrogen plasma treatment at specific stages of an ALD cycle configured to regulate chemical reaction pathways and enhance film electrical properties. The HM-ALD process may operate in two main modes:

(1) HAR (Hydrogen After Reactant) Mode: After the reactant (e.g., oxidant H₂O) pulse and purge steps, a hydrogen plasma treatment is performed. This plasma step provides additional energy to promote an increase in film density, similar to the effect of the ALA-ALD process.

(2) HAP (Hydrogen After Precursor) Mode: After the precursor (e.g., tetrakis (dimethylamino) hafnium, TDMAHf) pulse and purge steps, a hydrogen plasma treatment is performed. The key function of this step is to effectively remove organic ligands from adsorbed precursor molecules on the surface, thereby reducing steric hindrance and enabling more complete subsequent reactions with the reactant. Experimental data indicate that hafnium oxide (HfO₂) thin films formed by the HAP mode achieve a leakage current density as low as 1.17×10⁻⁹ A/cm²—approximately 6 orders of magnitude lower than that of films produced by conventional ALD processes—concurrent with a substantially reduced interfacial defect density (Dᵢₜ).

### 3. Plasma-Activated Precursor Atomic Layer Deposition (PAP-ALD) Process:

The PAP-ALD process utilizes plasma to directly activate a precursor, thereby enhancing a reactivity thereof. In one exemplary implementation (using BN thin films as an example), the process includes: Step 1: Precursor activation—concurrently introducing a precursor (e.g., tris(dimethylamino)borane, TDMAB) pulse and an argon plasma to directly activate precursor molecules via plasma energy; Step 2: performing an argon purge; Step 3: introducing a nitrogen plasma to react with the surface species; Step 4: performing an argon purge. The PAP-ALD process not only increases deposition rate but also is capable of controlling BN growth orientation (e.g., h-BN growing in a direction substantially perpendicular to the substrate surface as described above). In addition, PAP-ALD can mitigate a reliance on specific highly reactive precursors.

### Other Applicable Modified ALD Processes:

Embodiments of the present invention further encompass ultraviolet-enhanced ALD (UV-enhanced ALD) processes that utilize UV light to decompose precursors or promote reactions; plasma-enhanced atomic layer deposition (PEALD) processes that employ plasma to activate reactants and reduce deposition temperatures; multiple-pulse atomic layer deposition (multiple-pulse ALD) processes that apply multiple precursor or reactant pulses within a single cycle to enhance deposition rate and film properties while improving step coverage in high-aspect-ratio structures; and exposure-mode atomic layer deposition (exposure-mode ALD) processes that extend the residence time of precursors or reactants in the reaction chamber to allow more thorough diffusion to deposition surfaces, thereby enhancing deposition rate, uniformity, and film properties, as well as further improving step coverage in high-aspect-ratio structures.

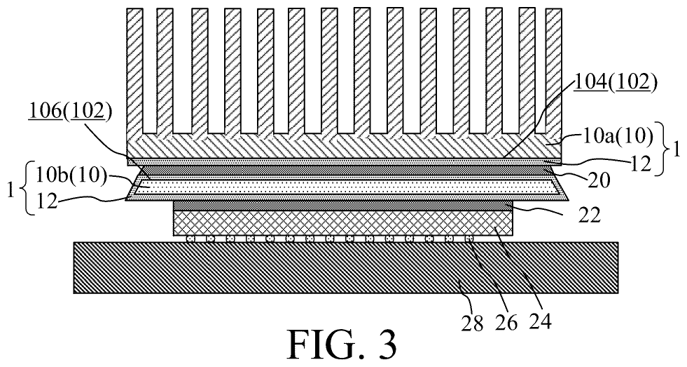

Referring to FIG. 3, FIG. 3 is a cross-sectional schematic diagram of a heat dissipation module 1 according to the first embodiment of the present invention, as well as its application environment and associated cooperating components.

As shown in FIG. 3, the heat dissipation module 1 according to the first embodiment of the present invention includes a heat-dissipating device 10 and an ultra-thin thermally conductive insulating layer 12. The heat-dissipating device 10 has a predetermined surface 102. The ultra-thin thermally conductive insulating layer 12 is formed to overlay the predetermined surface 102 of the heat-dissipating device 10.

In particular, the ultra-thin thermally conductive insulating layer 12 is formed by an ALD-based process. The thickness of the ultra-thin thermally conductive insulating layer 12 is equal to or less than 50 nanometers, and the leakage current density of the ultra-thin thermally conductive insulating layer 12 is equal to or less than 10⁻⁶ A/cm².

In one specific embodiment, as shown in the example of FIG. 3, the heat-dissipating device 10 includes a heatsink 10a or a heat spreader 10b. The predetermined surface 102 is the contact surface configured to interface with the thermal interface materials (20, 22); specifically, the bottom surface 104 of the heatsink 10a and the outer surface 106 of the heat spreader 10b. In FIG. 3, the chip 24 includes a plurality of bumps 26, and is electrically coupled to a circuit board 28 via the plurality of bumps 26. The heat spreader 10b is disposed over the chip 24, and the thermal interface material 22 is filled between the heat spreader 10b and the chip 24. The heatsink 10a is disposed over the heat spreader 10b, and the thermal interface material 20 is filled between the heatsink 10a and the heat spreader 10b. The ultra-thin thermally conductive insulating layer 12 of the present invention provides electrical insulation between the heatsink 10a and the thermal interface material 20, as well as between the heat spreader 10b and the thermal interface material 22, while facilitating thermal conduction therebetween. It should be emphasized that, by virtue of the ultra-thin thermally conductive insulating layer 12 overlaying the bottom surface 104 of the heatsink 10a and the outer surface 106 of the heat spreader 10b, the thermal interface materials 20 and 22 may include TIMs with high thermal conductivity to enhance heat dissipation performance and reliability of the chip 24. In addition, the ultra-thin thermally conductive insulating layer 12 of the present invention can also serve as a surface passivation layer for the chip 24.

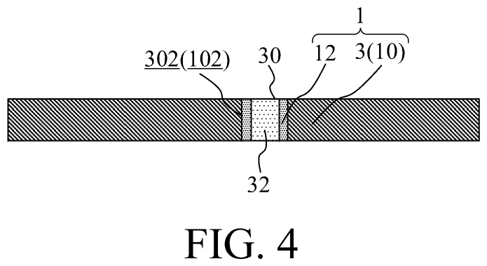

Referring to FIG. 4, FIG. 4 is a cross-sectional schematic view of another application scenario of the heat dissipation module 1 according to the first preferred embodiment of the present invention.

As shown in FIG. 4, in this embodiment, the heat-dissipating device 10 includes a silicon interposer 3. The predetermined surface 102 is the inner wall 302 of a through-silicon via 30 in the silicon interposer 3. While the silicon interposer 3 typically includes a plurality of through-silicon vias 30, only one through-silicon via 30 is illustrated in FIG. 4 as a representative example. The ultra-thin thermally conductive insulating layer 12 serves as an insulating liner to electrically isolate the conductive material 32 within the through-silicon via 30 from the silicon interposer 3 and to provide a radial heat conduction path.

In one embodiment, the atomic layer deposition-based process is selected from the group consisting of a conventional thermal atomic layer deposition (thermal-ALD) process, an atomic layer annealing-enhanced atomic layer deposition (ALA-ALD) process, a hydrogen-manipulated atomic layer deposition (HM-ALD) process, a plasma-activated precursor atomic layer deposition (PAP-ALD) process, an ultraviolet-enhanced atomic layer deposition (UV-enhanced ALD) process, a plasma-enhanced atomic layer deposition (PEALD) process, a multiple-pulse atomic layer deposition (multiple-pulse ALD) process, an exposure-mode atomic layer deposition (exposure-mode ALD) process, other atomic layer deposition-based processes, and combinations thereof.

In one embodiment, the ultra-thin thermally conductive insulating layer 12 according to the present invention may be formed of a metal oxide or a metalloid oxide. The metal oxide or the metalloid oxide may be selected from the group consisting of HfO₂, ZrO₂, HfₓZr₁₋ₓO₂ (0≤x≤1), Ta₂O₃, Al₂O₃, Gd₂O₃, La₂O₃, SiO₂, TiO₂, Y₂O₃, other metal oxides, other metalloid oxides, and combinations thereof.

In another embodiment, the ultra-thin thermally conductive insulating layer 12 according to the present invention may be formed of a metal nitride or a metalloid nitride. The metal nitride or the metalloid nitride may be selected from the group consisting of AlNₓ, SiNₓ, GeNₓ, BNₓ, other metal nitrides, other metalloid nitrides, and combinations thereof, wherein 0.5≤x≤1.5.

In one embodiment, the thickness of the ultra-thin thermally conductive insulating layer 12 ranges from 3 nm to 50 nm. The thermal conductance per unit area of the ultra-thin thermally conductive insulating layer 12 is equal to or greater than 50 MW/m²·K.

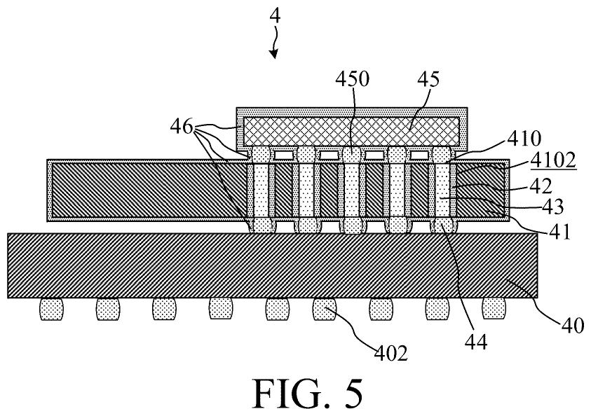

Referring to FIG. 5, FIG. 5 is a cross-sectional schematic view illustrating a semiconductor packaging structure 4 according to the second preferred embodiment of the present invention. As shown in FIG. 5, the semiconductor packaging structure 4 includes a substrate 40, an interposer 41, a plurality of metal plugs 43, a plurality of first bumps 44, at least one chiplet 45, and a first ultra-thin thermally conductive insulating layer 46. In FIG. 5, only one chiplet 45 is illustrated as a representative example.

The interposer 41 includes a plurality of interposer vias 410. The interposer 41 may be a silicon interposer or a glass interposer. In embodiments wherein the interposer 41 is a silicon interposer, the plurality of interposer vias 410 are through-silicon vias (TSVs). In embodiments wherein the interposer 41 is a glass interposer, the plurality of interposer vias 410 are through-glass vias (TGVs). The interposer 41 is disposed over the substrate 40.

Each of the plurality of metal plug 43 corresponds to one of the plurality of interposer vias 410, and fills within corresponding interposer via 410. Each of the plurality of first bump 44 corresponds to one of the plurality of metal plugs 43, and is electrically coupled between the corresponding metal plug 43 and the substrate 40. The at least one chiplet 45 is disposed on the interposer 41. Each chiplet 45 includes a plurality of second bumps 450. Each of the plurality of second bump 450 is electrically coupled to a corresponding one of the plurality of metal plugs 43. The first ultra-thin thermally conductive insulating layer 46 is conformally disposed over at least portions of the at least one chiplet 45, the interposer 41, the plurality of first bumps 44, and the plurality of second bumps 450. The substrate 40 also has a plurality of bumps 402. The first ultra-thin thermally conductive insulating layer 46 is formed by a first atomic layer deposition-based process. The first thickness of the first ultra-thin thermally conductive insulating layer 46 is equal to or less than 50 nm, and the first leakage current density of the first ultra-thin thermally conductive insulating layer 46 is equal to or less than 10⁻⁶ A/cm². It should be emphasized that each chiplet 45 is initially devoid of surface passivation layer formed thereon prior to formation of the first ultra-thin thermally conductive insulating layer 46, and the first ultra-thin thermally conductive insulating layer 46 serves as the surface passivation layer for each chiplet 45 while exhibiting high thermal conduction capability. Furthermore, by virtue of the first ultra-thin thermally conductive insulating layer 46 overlaying the surface of the at least one chiplet 45 and the outer surface of the interposer 41, a TIM with high thermal conductivity can be employed to fill gaps between the at least one chiplet 45 and the interposer 41, thereby enhancing the heat dissipation performance and reliability of the at least one chiplet 45. The semiconductor packaging structure 4 shown in FIG. 5 may be regarded as an example of a 2.5D semiconductor packaging structure.

In embodiments wherein the interposer 41 is a silicon interposer and the plurality of interposer vias 410 are through-silicon vias (TSVs), the semiconductor packaging structure 4 according to the second preferred embodiment of the present invention also includes a plurality of the second ultra-thin thermally conductive insulating layers 42. Each of the plurality of the second ultra-thin thermally conductive insulating layer 42 corresponds to one of the through-silicon vias, and is formed to overlay the respective inner wall 4102 of the corresponding through-silicon via. The plurality of the second ultra-thin thermally conductive insulating layers 42 are formed by the second atomic layer deposition-based process. The second thickness of each of the plurality of the second ultra-thin thermally conductive insulating layer 42 is equal to or less than 50 nm, and the second leakage current density of each of the plurality of the second ultra-thin thermally conductive insulating layer 42 is equal to or less than 10⁻⁶ A/cm².

In one embodiment, the first atomic layer deposition-based process and the second atomic layer deposition-based process may be independently selected from the group consisting of a conventional thermal atomic layer deposition (thermal-ALD) process, an atomic layer annealing-enhanced atomic layer deposition (ALA-ALD) process, a hydrogen-manipulated atomic layer deposition (HM-ALD) process, a plasma-activated precursor atomic layer deposition (PAP-ALD) process, an ultraviolet-enhanced atomic layer deposition (UV-enhanced ALD) process, a plasma-enhanced atomic layer deposition (PEALD) process, a multiple-pulse atomic layer deposition (multiple-pulse ALD) process, an exposure-mode atomic layer deposition (exposure-mode ALD) process, other atomic layer deposition-based processes, and combinations thereof.

In one embodiment, the first ultra-thin thermally conductive insulating layer 46 and the second ultra-thin thermally conductive insulating layers 42 may respectively be formed of one selected from the group consisting of a metal oxide, a metalloid oxide, a metal nitride and a metalloid nitride. The metal oxide or the metalloid oxide may be selected from the group consisting of HfO₂, ZrO₂, HfₓZr₁₋ₓO₂ (0)≤x≤1), Ta₂O₃, Al₂O₃, Gd₂O₃, La₂O₃, SiO₂, TiO₂, Y₂O₃, other metal oxides, other metalloid oxides, and combinations thereof. The metal nitride of the metalloid nitride may be selected from the group consisting of AlNₓ, SiNₓ, GeNₓ, BNₓ, other metal nitrides, other metalloid nitrides, and combinations thereof, wherein 0.5≤x≤1.5.

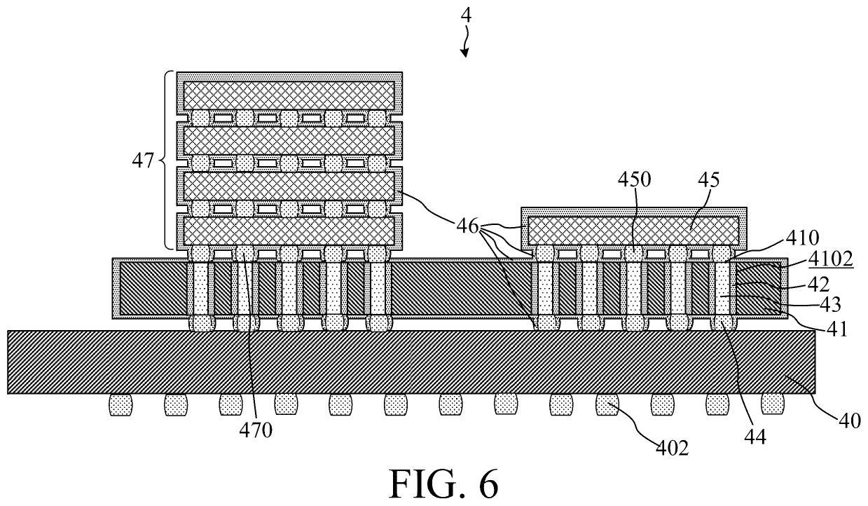

Referring to FIG. 6, FIG. 6 schematically illustrates a modification of the semiconductor packaging structure 4 according to the second preferred embodiment of the present invention. As shown in FIG. 6, furthermore, the semiconductor packaging structure 4 according to the second preferred embodiment of the present invention also includes a chiplet stack 47. The chiplet stack 47 is disposed on the interposer 41. The chiplet stack 47 includes a plurality of third bumps 470. Each of the plurality of the third bump 470 corresponds to one of the plurality of metal plugs 43, and is electrically coupled to a corresponding metal plug 43. The first ultra-thin thermally conductive insulating layer 46 is conformally also overlays the entire outer surface of the chiplet stack 47. It should be emphasized that the chiplet stack 47 is initially devoid of surface passivation layer formed thereon prior to formation of the first ultra-thin thermally conductive insulating layer 46, and the first ultra-thin thermally conductive insulating layer 46 serves as the surface passivation layer for the chiplet stack 47 while exhibiting high thermal conduction capability. Furthermore, by virtue of the first ultra-thin thermally conductive insulating layer 46 overlaying the surface of the chiplet stack 47 and the outer surface of the interposer 41, a TIM with high thermal conductivity can be employed to fill gaps inside the chiplet stack 47 and gaps between the chiplet stack 47 and the interposer 41, thereby enhancing the heat dissipation performance and reliability of the chiplet stack 47. The semiconductor packaging structure 4 shown in FIG. 6 may be regarded as an example of a 3D semiconductor packaging structure. Chiplets within the chiplet stack 47 may be vertically interconnected using through-silicon vias (not shown), metal plugs (not shown), and bumps.

In the first example, the second example, and the third example of the present invention, hafnium oxide (HfO₂) ultra-thin thermally conductive insulating layers were fabricated to form metal-oxide-semiconductor (MOS) capacitor devices. In these three examples, the total physical thickness of the HfO₂ ultra-thin insulating layer and its interfacial layer thereof was approximately 5.3 nm. The MOS capacitor devices were fabricated on p-type (100)-oriented silicon substrates with a resistivity of 1-10 Ω·cm. The structure, from bottom to top, sequentially includes an aluminum (Al) back electrode, the p-Si substrate, the hafnium oxide (HfO₂) high-k dielectric layer, and a tungsten (W) top electrode. The precursor used in the first example, the second example, and the third example was tetrakis(dimethylamino)hafnium (TDMAHf), and the reactant was water vapor (H₂O). The deposition temperature for the HfO₂ ultra-thin thermally conductive insulating layer is set at 300° C.

The first example of the present invention employs the HAR process described herein, wherein the energy provided by hydrogen plasma was transferred to the freshly deposited atomic layer of HfO₂, promoting migration and rearrangement of surface adatoms to achieve atomic-layer-level annealing effects, thereby improving the density and structure of the HfO₂ film. In the first example of the present invention, the hydrogen plasma treatment was performed using a plasma power of 50 W and a plasma exposure duration of 7.5 seconds.

The second example of the present invention employed the HAP process described herein. In this process, prior to introducing the H₂O reactant, a hydrogen plasma treatment was utilized to effectively remove organic ligands from TDMAHf molecules adsorbed on the surface. The removal of these ligands substantially reduces steric hindrance, allowing subsequent H₂O molecules to undergo more complete chemical reactions with Hf atoms, thereby forming HfO₂ films with reduced defect density and enhanced film properties. The third example employed a conventional thermal-ALD process.

The MOS capacitor devices containing HfO₂ ultra-thin thermally conductive insulating layers fabricated in the first example, the second example, and the third example of the present invention were subjected to a 5-minute rapid thermal annealing at 450° C. in a forming gas atmosphere containing 5% H₂/95% N₂ to complete post-metallization annealing (PMA).

Leakage current density-voltage measurements were performed on the MOS capacitor devices of the first example, the second example, and the third example. The leakage current density (J_{g}) is defined as the current density measured at the flatband voltage (V_{FB}) minus 1 volt (V_{FB}-1V). The device of the third example (using a conventional thermal-ALD process) exhibited a leakage current density (J_{g}) of 1.62×10⁻³ A/cm². In contrast, the devices of the first example (HAR) and the second example (HAP) exhibited J_{g} values that were substantially reduced to 1.25×10⁻⁹ A/cm² and 1.17×10⁻⁹ A/cm², respectively. This reduction in leakage current exceeds six orders of magnitude, demonstrating the effectiveness of the method of the invention in suppressing leakage current density. These results support that the leakage current density of the ultra-thin thermally conductive insulating layer fabricated according to embodiments of the present invention is equal to or less than 10⁻⁶ A/cm², and can even be lower than 2×10⁻⁹ A/cm². Relevant electrical parameters including interfacial state density (Dᵢₜ) for the three devices are summarized in Table 1 below. Although the HfO₂ ultra-thin thermally conductive insulating layer with a thickness of 5.33 nm fabricated by the conventional thermal-ALD process in the third example exhibited a J_{g} as high as 1.62×10⁻³ A/cm² (which may not meet the stringent low leakage specification), it is noted that if the thickness of the ultra-thin thermally conductive insulating layer fabricated by the conventional thermal-ALD process is moderately increased while remaining controlled below 50 nm, its corresponding J_{g} can still meet the specification of no greater than 10⁻⁶ A/cm² as required by the present invention.

TABLE 1

| | device | | |
|---|---|---|---|
| | first | second | third |
| electrical parameter | example | example | example |
| thickness of | 5.30 | 5.28 | 5.33 |
| insulating layer (nm) | | | |
| J_{g}(A/cm²) | 1.25 × 10⁻⁹ | 1.17 × 10⁻⁹ | 1.62 × 10⁻³ |
| Dᵢₜ (#/cm²) | 8.05 × 10¹¹ | 5.25 × 10¹¹ | 9.27 × 10¹¹ |

The interfacial state density (Dᵢₜ) results listed in Table 1 show that, compared to the conventional thermal-ALD process, the interfacial state density (Dᵢₜ) of the ultra-thin thermally conductive insulating layer formed by the HAR and HAP processes of the present invention is substantially reduced.

To explore the physical mechanism underlying the significant reduction in leakage current, X-ray reflectivity (XRR) measurement was employed to analyze the density of the ultra-thin thermally conductive insulating layer. By fitting the XRR spectra, the film density can be accurately obtained. The density of the HfO₂ ultra-thin thermally conductive insulating layer formed by the conventional thermal-ALD process is 8.71 g/cm³. The density of the HfO₂ ultra-thin thermally conductive insulating layer formed by the HAR process is increased to 9.16 g/cm³. The density of the HfO₂ ultra-thin thermally conductive insulating layer formed by the HAP process reaches the highest value of 9.44 g/cm³. The significant increase in the density of the ultra-thin thermally conductive insulating layer indicates a more compact atomic arrangement and reduced defects and voids, thereby effectively impeding leakage current paths. This result is highly correlated with the leakage current measurement data, i.e., the HAP device exhibiting the highest film density corresponds to the lowest observed leakage current.

In the fourth example and the fifth example of the present invention, aluminum oxide (Al₂O₃) ultra-thin thermally conductive insulating layers were fabricated to form metal-insulator-semiconductor (MIS) and metal-insulator-metal (MIM) capacitor devices. The MIS capacitor device (the fourth example) was fabricated on a p-type silicon substrate, with a structure from bottom to top being an aluminum (Al) back electrode, the p-Si substrate, the Al₂O₃ insulating layer, and a tungsten (W) top electrode. The structure of the MIM capacitor device (the fifth example), stacked in sequence from bottom to top, includes a Si substrate, a titanium nitride (TiN) adhesion layer, a tungsten (W) bottom electrode, the Al₂O₃ insulating layer, and a tungsten (W) top electrode. The precursor used in both the fourth example and the fifth example was trimethylaluminum (TMA), and the reactant was oxygen plasma, using a plasma-enhanced atomic layer deposition (PEALD) process to prepare the Al₂O₃ thin film, with a film deposition temperature set to 300° C. Both the MIS and MIM capacitor devices in the fourth example and the fifth example were subjected to rapid thermal annealing for 5 minutes at 400° C. in a forming gas atmosphere containing 5% H₂/95% N₂ to complete post-metallization annealing (PMA).

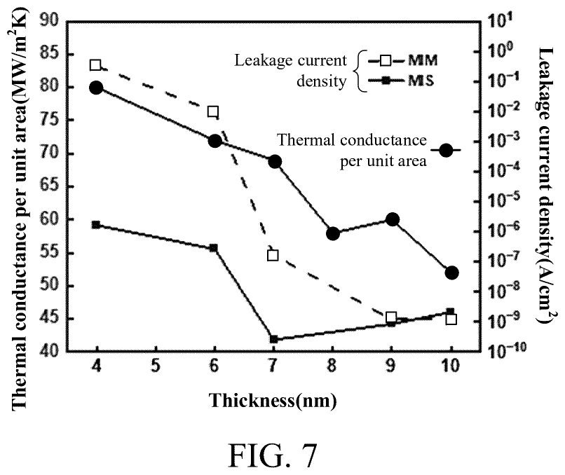

Referring to FIG. 7, FIG. 7 shows a graph of the relationship between thermal conductance per unit area and leakage current density versus film thickness for aluminum oxide (Al₂O₃) ultra-thin thermally conductive insulating layers. The thermal conductance per unit area therein was obtained by time-domain thermoreflectance (TDTR) measurement, derived from a transient heat transfer response analysis of the Al₂O₃ thin film deposited on a Si substrate. The leakage current density (J_{g}) of the MIS and MIM capacitor devices represents the current density value measured at an applied voltage of −1V. As demonstrated in FIG. 7, both the thermal conductance per unit area and the leakage current density of the Al₂O₃ thin films exhibit a gradual decreasing trend with increasing film thickness. When the thickness reaches about 10 nanometers, the thermal conductance per unit area of the Al₂O₃ ultra-thin thermally conductive insulating layer is greater than 50 MW/m²·K, and J_{g} is suppressed to approximately 10⁻⁹ A/cm². This result confirms that the ultra-thin insulating layer fabricated according to the method of the present invention meets the claimed specifications, specifically: a leakage current density is equal to or less than 1×10⁻⁶ A/cm² and a thermal conductance per unit area is equal to or greater than 50 MW/m²·K.

In the sixth example and the seventh example of the present invention, aluminum nitride (AlN) ultra-thin thermally conductive insulating layers were fabricated to form MIS and MIM capacitor devices. The MIS capacitor device (the sixth example) is fabricated on a p-type silicon substrate, with a structure from bottom to top being an aluminum (Al) back electrode, the p-Si substrate, the AlN insulating layer, and a tungsten (W) top electrode. The structure of the MIM capacitor device (the seventh example), stacked in sequence from bottom to top, includes a Si substrate, a titanium nitride (TiN) adhesion layer, a tungsten (W) bottom electrode, the AlN insulating layer, and a tungsten (W) top electrode. The precursor used in both the sixth example and the seventh example was trimethylaluminum (TMA), and the reactant was nitrogen plasma. The HAR mode in the hydrogen-manipulated atomic layer deposition (HM-ALD) process was employed to prepare the AlN thin films, with a film deposition temperature set to 300° C. In the sixth example and the seventh example, the MIS and MIM capacitor devices were not subjected to post-annealing treatment.

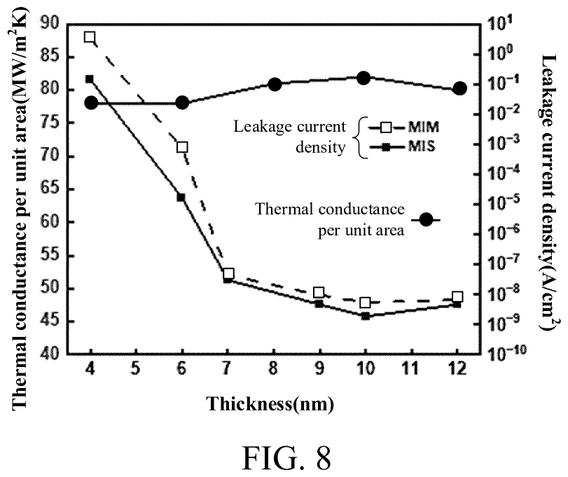

Referring to FIG. 8, FIG. 8 shows a graph of the relationship between thermal conductance per unit area and leakage current density versus film thickness for aluminum nitride (AlN) ultra-thin thermally conductive insulating layers. The thermal conductance per unit area therein was obtained by time-domain thermoreflectance (TDTR) measurement, derived from a transient heat transfer response analysis of the AlN thin film deposited on a Si substrate. The leakage current density (J_{g}) of the MIS and MIM capacitor devices represents the current density value measured at an applied voltage of −1V. As demonstrated in FIG. 8, the leakage current density of the AlN thin film significantly decreases with increasing film thickness. Notably, attributed to the high intrinsic thermal conductivity of AlN, the films maintain a high and substantially stable thermal conductance per unit area of approximately 80 MW/m²·K within the thickness range of 4-12 nanometers. This demonstrates its excellent heat transfer capability at the nanoscale. Specifically, when the thickness reaches about 10 nanometers, the thermal conductance per unit area of the AlN ultra-thin thermally conductive insulating layer is greater than 75 MW/m²·K, and J_{g} is approximately 10⁻⁹ A/cm². This result confirms that the ultra-thin insulating layer fabricated according to the method of the present invention meets the claimed specifications, specifically: a leakage current density is equal to or less than 1×10⁻⁶ A/cm² and a thermal conductance per unit area is equal to or greater than 50 MW/m²·K.

Through the above detailed description of the present invention, it can be clearly understood that the present invention minimizes the thermal resistance by reducing the thickness of the insulating layer, thereby achieving excellent thermal conduction performance. Concurrently, a high-quality thin film is formed by an ALD-based process to meet the stringent electrical insulation requirement. This unique combination of properties not only significantly expands design flexibility within heat dissipation modules for integration with thermal interface materials (TIMs) having high thermal conduction performance, but also further enhances the heat dissipation performance and long-term reliability of 2.5D, 3D, and other advanced semiconductor packaging structures.

The detailed description provided above illustrates the features and spirit of the present invention. Those skilled in the art will readily observe that numerous modifications and alterations of the device and method may be made while retaining the teaching of the invention. Accordingly, the above disclosure should be construed as limited only by the metes and bounds of the appended claims.

What is claimed is:

1. A heat dissipation module, comprising:
a heat-dissipating device, having a predetermined surface; and
an ultra-thin thermally conductive insulating layer, formed to overlay a predetermined surface of the heat-dissipating device,
wherein the ultra-thin thermally conductive insulating layer is formed by an atomic layer deposition based (ALD-based) process, a thickness of the ultra-thin thermally conductive insulating layer is equal to or less than 50 nanometers, and a leakage current density of the ultra-thin thermally conductive insulating layer is equal to or less than 10⁻⁶ A/cm².

2. The heat dissipation module of claim 1, wherein the ALD-based process is selected from the group consisting of a conventional thermal atomic layer deposition process, an atomic layer annealing-enhanced atomic layer deposition process, a hydrogen-manipulated atomic layer deposition process, a plasma-activated precursor atomic layer deposition process, an ultraviolet-enhanced atomic layer deposition process, a plasma-enhanced atomic layer deposition process, a multiple-pulse atomic layer deposition process, and an exposure-mode atomic layer deposition process, and combinations thereof.

3. The heat dissipation module of claim 1, wherein the heat-dissipating device comprises a heat sink or a heat spreader, the predetermined surface comprises a contact surface configured to contact a thermal interface material (TIM), and the ultra-thin thermally conductive insulating layer is configured to electrically isolate the heat sink or the heat spreader from the thermal interface material while maintaining a thermal conduction path therebetween.

4. The heat dissipation module of claim 1, wherein the heat-dissipating device comprises a silicon interposer, the predetermined surface comprises an inner wall of a through-silicon via (TSV) defined within the silicon interposer, and the ultra-thin thermally conductive insulating layer serves as an insulating liner configured to electrically isolate a conductive material disposed within the through-silicon via from the silicon interposer while providing a radial thermal conduction path.

5. The heat dissipation module of claim 1, wherein the ultra-thin thermally conductive insulating layer is formed of one selected from the group consisting of a metal oxide, a metalloid oxide, a metal nitride and a metalloid nitride, wherein the metal oxide or the metalloid oxide is selected from the group consisting of HfO₂, ZrO₂, HfₓZr₁₋ₓO₂ (0≤x≤1), Ta₂O₃, Al₂O₃, Gd₂O₃, La₂O₃, SiO₂, TiO₂, and Y₂O₃, and combinations thereof; and wherein the metal nitride or the metalloid nitride is selected from the group consisting of AlNₓ, SiNₓ, GeNₓ, and BNₓ, and combinations thereof, wherein 0.5≤x≤1.5.

6. The heat dissipation module of claim 1, wherein the thickness of the ultra-thin thermally conductive insulating layer ranges from 3 nanometers to 50 nanometers, and a thermal conductance per unit area of the ultra-thin thermally conductive insulating layer is equal to or greater than 50 MW/m²·K.

7. A semiconductor packaging structure, comprising:
a substrate;
an interposer, having a plurality of interposer vias, the interposer being disposed over the substrate, wherein the interposer is a silicon interposer or a glass interposer: wherein when the interposer is the silicon interposer, the plurality of interposer vias are through-silicon vias (TSVs); and when the interposer is the glass interposer, the plurality of interposer vias are through-glass vias (TGVs);
a plurality of metal plugs, each metal plug corresponding to one of the interposer vias and disposed within the corresponding interposer via;
a plurality of first bumps, each first bump corresponding to one of the metal plugs and being electrically coupled to the corresponding metal plug and the substrate;
at least one chiplet, disposed on the interposer, each chiplet having a plurality of second bumps, each second bump corresponding to one of the metal plugs and being electrically coupled to the corresponding metal plug; and
a first ultra-thin thermally conductive insulating layer, formed to overlay the at least one chiplet, the interposer, the plurality of first bumps, and the plurality of second bumps; wherein the first ultra-thin thermally conductive insulating layer is formed by a first ALD-based process; and wherein a first thickness of the first ultra-thin thermally conductive insulating layer is equal to or less than 50 nanometers, and a first leakage current density of the first ultra-thin thermally conductive insulating layer is equal to or less than 10⁻⁶ A/cm².

8. The semiconductor packaging structure of claim 7, wherein when the interposer is the silicon interposer and the plurality of interposer vias are the through-silicon vias, the semiconductor packaging structure further comprises:
a plurality of second ultra-thin thermally conductive insulating layers, each second ultra-thin thermally conductive insulating layer corresponding to one of the through-silicon vias and being formed to overlay a respective inner wall of the corresponding through-silicon via, wherein the plurality of second ultra-thin thermally conductive insulating layers are formed by a second ALD-based process, a second thickness of each second ultra-thin thermally conductive insulating layer is equal to or less than 50 nanometers, and a second leakage current density of each second ultra-thin thermally conductive insulating layer is equal to or less than 10⁻⁶ A/cm².

9. The semiconductor packaging structure of claim 8, wherein the first ALD-based process and the second ALD-based process are each independently selected from the group consisting of a conventional thermal atomic layer deposition process, an atomic layer annealing-enhanced atomic layer deposition process, a hydrogen-manipulated atomic layer deposition process, a plasma-activated precursor atomic layer deposition process, an ultraviolet-enhanced atomic layer deposition process, a plasma-enhanced atomic layer deposition process, a multiple-pulse atomic layer deposition process, and an exposure-mode atomic layer deposition process, and combinations thereof: wherein the first ultra-thin thermally conductive insulating layer and the plurality of second ultra-thin thermally conductive insulating layers each are respectively formed of one selected from the group consisting of a metal oxide, a metalloid oxide, a metal nitride and a metalloid nitride; wherein the metal oxide or the metalloid oxide is selected from the group consisting of HfO₂, ZrO₂, HfₓZr₁₋ₓO₂ (0≤x≤1), Ta₂O₃, Al₂O₃, Gd₂O₃, La₂O₃, SiO₂, TiO₂, and Y₂O₃, and combinations thereof; and wherein the metal nitride or the metalloid nitride is selected from the group consisting of AlNₓ, SiNₓ, GeNₓ, and BNₓ, and combinations thereof, wherein 0.5≤x≤1.5.

10. The semiconductor packaging structure of claim 7, further comprising:
a chiplet stack, disposed on the interposer, the chiplet stack having a plurality of third bumps, each third bump corresponding to one of the metal plugs and being electrically coupled to the corresponding metal plug; wherein the first ultra-thin thermally conductive insulating layer also overlays an entire outer surface of the chiplet stack.
